(19) United States
(12) Patent Application Publication
(10) Pub. No.: US 2018/0342220 A1
(43) Pub. Date: Nov. 29, 2018

(54) SHIFT REGISTER CIRCUIT AND DISPLAY PANEL USING SAME

(71) Applicants: HKC Corporation Limited, Shenzhen City, Guangdong (CN); Chongqing HKC Optoelectronics Technology Co., Ltd., Chongqing (CN)

(72) Inventor: Yu-Jen CHEN, Chongqing (CN)

(21) Appl. No.: 15/555,883

(22) PCT Filed: Jul. 7, 2017
(86) PCT No.: PCT/CN2017/092139

§ 371 Date: Sep. 5, 2017

(30) Foreign Application Priority Data
May 27, 2017 (CN) 201710389743.6

(51) Int. Cl. G09G 3/36; G11C 19/28

(52) U.S. Cl. CPC G09G 3/3677; G09G 2320/0214; G09G 2310/0286; G11C 19/287

(57) ABSTRACT

Each Shift registers includes fourth switches and a voltage regulator circuit: a first switch: a control end electrically coupled to an input pulse signal, a first end electrically coupled to the input pulse signal, and a second end electrically coupled to a first node; a second switch: a control end electrically coupled to a second node, a first end electrically coupled to the first node, and a second end electrically coupled to a preset low potential; a third switch: a control end electrically coupled to a third node, a first end electrically coupled to a frequency signal, and a second end electrically coupled to an output end; a fourth switch: a control end electrically coupled to the second node, a first end electrically coupled to the output end, and a second end electrically coupled to the preset low potential.

### BACKGROUND

### Technical Field

This application relates to a circuit structure in a display, and in particular, to a shift register circuit and a display panel using same.

### Related Art

In recent years, with progress of science and technologies, flat displays gradually become popular and have advantages such as lightness and slimness. Currently, a driver circuit of a flat display is formed by connecting an external IC to a panel. However, this method cannot lower product costs or make the panel slimmer.

In addition, a display device usually includes a gate driver circuit, a source driver circuit, and a pixel array. The pixel array includes a plurality of pixel circuits. Each pixel circuit is switched on or off according to a scanning signal provided by the gate driver circuit. A data screen is displayed according to a data signal provided by the source driver circuit. With regard to the gate driver circuit, the gate driver circuit usually includes a plurality of stages of shift registers and outputs the scanning signal to the pixel array by transferring the scanning signal from a current-stage shift register to a next-stage shift register, so as to sequentially switch on the pixel circuits and enable the pixel circuits to receive the data signal.

Therefore, in a manufacturing process of a driver circuit, a gate driver circuit is directly manufactured on an array substrate to replace a driver chip made from a connected external IC. Such a technology, referred to as Gate On Array (GOA), may be directly applied to a periphery of a panel, to reduce manufacturing procedures, product costs, and a thickness of the panel. In the GOA technology, a speed at which a shift register pulls down a gate signal usually affects an effect of driving a pixel array using a gate signal. However, because of a setting on a time sequence of an existing panel and a leakage current likely to be generated when a switch component in a shift register switches on/off a voltage, a speed at which the shift register pulls down a gate signal is reduced. If the speed at which the gate signal is pulled down can be effectively increased, a display screen of the entire panel can be optimized, thereby improving quality of the display screen. Therefore, to alleviate disadvantages of the foregoing conventional GOA circuit substrate technology, a gate array shift register having low manufacturing costs and an easy processing procedure is provided.

### SUMMARY

To resolve the foregoing technical problem, an objective of this application is to provide a shift register circuit. Two active switches are configured to control a node potential, so that a potential at a pull-up point can be prevented from an electrical leakage and maintained at a voltage level. In this way, a service life of a component is prolonged, and reliability of a product can be improved and a service life of the product can be prolonged.

The objective of this application is achieved and the technical problem of this application is resolved by using the following technical solutions.

A shift register circuit is provided according to this application, comprising a plurality of stages of shift registers, where each shift register comprises: a first switch, where a control end of the first switch is electrically coupled to an input pulse signal, a first end of the first switch is electrically coupled to the input pulse signal, and a second end of the first switch is electrically coupled to a first node; a second switch, where a control end of the second switch is electrically coupled to a second node, a first end of the second switch is electrically coupled to the first node, and a second end of the second switch is electrically coupled to a preset low potential; a third switch, where a control end of the third switch is electrically coupled to a third node, a first end of the third switch is electrically coupled to a frequency signal, and a second end of the third switch is electrically coupled to an output end; a fourth switch, where a control end of the fourth switch is electrically coupled to the second node, a first end of the fourth switch is electrically coupled to the output end, and a second end of the fourth switch is electrically coupled to the preset low potential; and a voltage regulator circuit, configured to maintain a potential of the first node and a potential of the third node at a voltage level.

In an embodiment of this application, the voltage regulator circuit further comprises a fifth switch, where a control end of the fifth switch is electrically coupled to the first node, a first end of the fifth switch is electrically coupled to the first node, and a second end of the fifth switch is electrically coupled to the third node.

In an embodiment of this application, the voltage regulator circuit further comprises a sixth switch, where a control end of the sixth switch is electrically coupled to the second node, a first end of the sixth switch is electrically coupled to the first node, and a second end of the sixth switch is electrically coupled to the third node.

In an embodiment of this application, the shift register circuit further comprises a capacitor configured to store an electric charge, to maintain the potential of the third node at a voltage level.

In an embodiment of this application, a first end of the fifth switch is electrically coupled to the first node, to receive a high potential when an input pulse signal is switched on.

In an embodiment of this application, a second end of the fifth switch is electrically coupled to the third node, to transfer a high potential when an input pulse signal is switched on, so as to conduct the high potential from the first node to the third node, thereby driving a third switch to act.

In an embodiment of this application, when acting, the third switch may transfer a signal indicating that a frequency signal changes from a low potential to a high potential to the output end.

In an embodiment of this application, a first end of the sixth switch is electrically coupled to the first node, to receive a low potential when an input pulse signal is switched on.

In an embodiment of this application, a second end of the sixth switch is electrically coupled to the third node, to transfer a low potential when an input pulse signal is switched on, so as to conduct the low potential from the first node to the third node, thereby preventing a third switch from acting.

Another objective of this application is to provide a display panel, comprising: a first substrate; a second substrate, disposed opposite to the first substrate; and the shift register circuit, disposed on the first substrate or the second substrate and comprising a plurality of stages of shift registers, where each shift register comprises: a first switch, where a control end of the first switch is electrically coupled to an input pulse signal, a first end of the first switch is electrically coupled to the input pulse signal, and a second end of the first switch is electrically coupled to a first node; a second switch, where a control end of the second switch is electrically coupled to a second node, a first end of the second switch is electrically coupled to the first node, and a second end of the second switch is electrically coupled to a preset low potential; a third switch, where a control end of the third switch is electrically coupled to a third node, a first end of the third switch is electrically coupled to a frequency signal, and a second end of the third switch is electrically coupled to an output end; a fourth switch, where a control end of the fourth switch is electrically coupled to the second node, a first end of the fourth switch is electrically coupled to the output end, and a second end of the fourth switch is electrically coupled to the preset low potential; and a voltage regulator circuit, configured to maintain a potential of the first node and a potential of the third node at a voltage level.

In an embodiment of this application, the voltage regulator circuit further comprises a fifth switch, where a control end of the fifth switch is electrically coupled to the first node, a first end of the fifth switch is electrically coupled to the first node, and a second end of the fifth switch is electrically coupled to the third node.

In an embodiment of this application, the voltage regulator circuit further comprises a sixth switch, where a control end of the sixth switch is electrically coupled to the second node, a first end of the sixth switch is electrically coupled to the first node, and a second end of the sixth switch is electrically coupled to the third node.

In an embodiment of this application, the display panel further comprises a capacitor configured to store an electric charge, to maintain the potential of the third node at a voltage level.

In an embodiment of this application, a first end of the fifth switch is electrically coupled to the first node, to receive a high potential when an input pulse signal is switched on.

In an embodiment of this application, a second end of the fifth switch is electrically coupled to the third node, to transfer a high potential when an input pulse signal is switched on, so as to conduct the high potential from the first node to the third node, thereby driving a third switch to act.

In an embodiment of this application, when acting, the third switch may transfer a signal indicating that a frequency signal changes from a low potential to a high potential to the output end.

In an embodiment of this application, a first end of the sixth switch is electrically coupled to the first node, to receive a low potential when an input pulse signal is switched on.

In an embodiment of this application, a second end of the sixth switch is electrically coupled to the third node, to transfer a low potential when an input pulse signal is switched on, so as to conduct the low potential from the first node to the third node, thereby preventing a third switch from acting.

The technical problem of this application may be further resolved by using the following technical solutions. A shift register circuit is provided, comprising a plurality of stages of shift registers, where each shift register comprises: a first switch, where a control end of the first switch is electrically coupled to an input pulse signal, a first end of the first switch is electrically coupled to the input pulse signal, and a second end of the first switch is electrically coupled to a first node; a second switch, where a control end of the second switch is electrically coupled to a second node, a first end of the second switch is electrically coupled to the first node, and a second end of the second switch is electrically coupled to a preset low potential; a third switch, where a control end of the third switch is electrically coupled to a third node, a first end of the third switch is electrically coupled to a frequency signal, and a second end of the third switch is electrically coupled to an output end; a fourth switch, where a control end of the fourth switch is electrically coupled to the second node, a first end of the fourth switch is electrically coupled to the output end, and a second end of the fourth switch is electrically coupled to the preset low potential; a voltage regulator circuit, comprising a fifth switch and a sixth switch, to maintain a potential of the first node and a potential of the third node at a voltage level; and a capacitor, configured to store an electric charge, to maintain the potential of the third node at a voltage level, where a control end of the fifth switch is electrically coupled to the first node, a first end of the fifth switch is electrically coupled to the first node, to receive a high potential when an input pulse signal is switched on, and a second end of the fifth switch is electrically coupled to the third node, to transfer a high potential when an input pulse signal is switched on; and a control end of the sixth switch is electrically coupled to the second node, a first end of the sixth switch is electrically coupled to the first node, to receive a low potential when an input pulse signal is switched on, and a second end of the sixth switch is electrically coupled to the third node, to transfer a low potential when an input pulse signal is switched on.

In this application, two active switches are configured to control a node potential, so that a potential at a pull-up point can be prevented from an electrical leakage and maintained at a voltage level. In this way, a service life of a component is prolonged, and reliability of a product can be improved and a service life of the product can be prolonged.

### BRIEF DESCRIPTION OF THE DRAWINGS

FIG. 1a is a schematic diagram of an exemplary liquid crystal display;

FIG. 1b is a schematic diagram of another exemplary liquid crystal display;

FIG. 2a is a schematic diagram of an exemplary ideal Thompson circuit;

FIG. 2b is a schematic waveform diagram of an exemplary ideal Thompson circuit;

FIG. 3a is a schematic diagram of an exemplary actual Thompson circuit;

FIG. 3b is a schematic waveform diagram of an exemplary actual Thompson circuit;

FIG. 4a is a schematic diagram of a shift register circuit according to an embodiment of this application;

FIG. 4b is a schematic waveform diagram of a shift register circuit according to an embodiment of this application; and

FIG. 5 is a schematic diagram of a liquid crystal display panel according to an embodiment of this application.

### DETAILED DESCRIPTION

The following embodiments are described with reference to the accompanying drawings, used to exemplify specific embodiments for implementation of this application. Terms about directions mentioned in this application, such as “on”, “below”, “front”, “back”, “left”, “right”, “in”, “out”, and “side surface” merely refer to directions in the accompanying drawings. Therefore, the used terms about directions are used to describe and understand this application, and are not intended to limit this application.

The accompanying drawings and the description are considered to be essentially exemplary, rather than limitative. In the figures, modules with similar structures are represented by using the same reference number. In addition, for understanding and ease of description, the size and the thickness of each component shown in the accompanying drawings are arbitrarily shown, but this application is not limited thereto.

In the accompanying drawings, for clarity, thicknesses of a layer, a film, a panel, an area, and the like are enlarged. In the accompanying drawings, for understanding and ease of description, thicknesses of some layers and areas are enlarged. It should be understood that when a component such as a layer, a film, an area, or a base is described to be “on” “another component”, the component may be directly on the another component, or there may be an intermediate component.

In addition, throughout this specification, unless otherwise explicitly described to have an opposite meaning, the word “include” is understood as including the component, but not excluding any other component. In addition, throughout the specification, “on” means that one is located above or below a target component and does not necessarily mean that one is located on the top based on a gravity direction.

To further describe the technical measures taken in this application to achieve the intended application objective and effects thereof, specific implementations, structures, features, and effects of a shift register circuit and a display panel using same provided according to this application are described below in detail with reference to the drawings and preferred embodiments.

A display panel in this application is, for example, a liquid crystal display panel, an OLED display panel, a QLED display panel, or another display panel. Using the liquid crystal display panel as an example, the liquid crystal display panel includes: an active array (thin film transistor (TFT)) substrate, a color filter (CF) substrate, and a liquid crystal layer formed between the two substrates.

In an embodiment, the display panel in this application may be a curved-surface display panel.

In an embodiment, the active array (TFT) and the CF in this application may be formed on a same substrate.

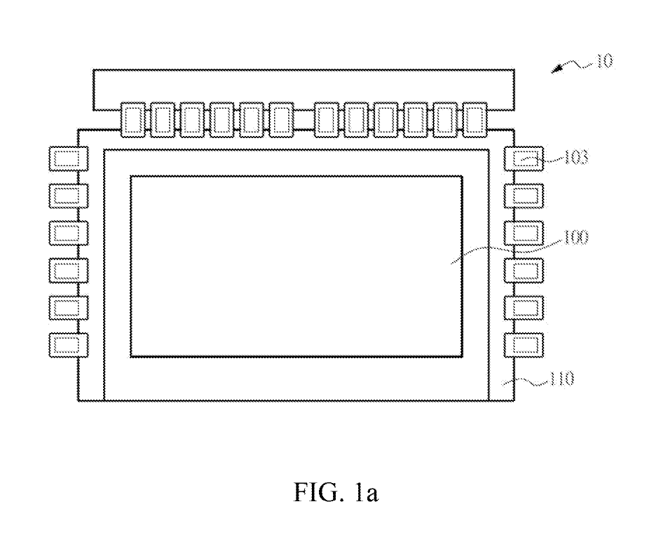

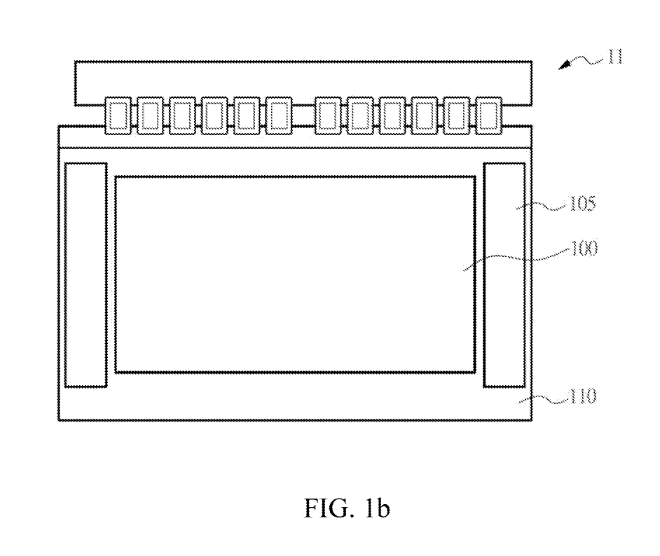

FIG. 1a is a schematic diagram of an exemplary liquid crystal display. Referring to FIG. 1a, a liquid crystal display 10 includes: a CF substrate 100, an active array substrate 110, and a driver chip 103 configured to drive a circuit.

FIG. 1b is a schematic diagram of a liquid crystal display according to an embodiment of this application. Referring to FIG. 1b, in an embodiment of this application, a liquid crystal display 11 having a GOA includes: a CF substrate 100, an active array substrate 110, and a GOA 105, configured to manufacture a gate driver circuit on the array substrate 110.

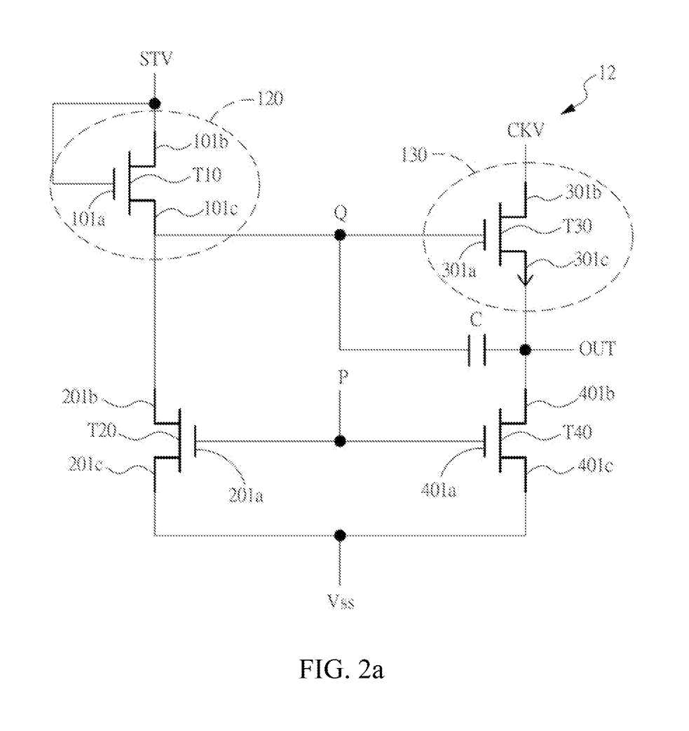

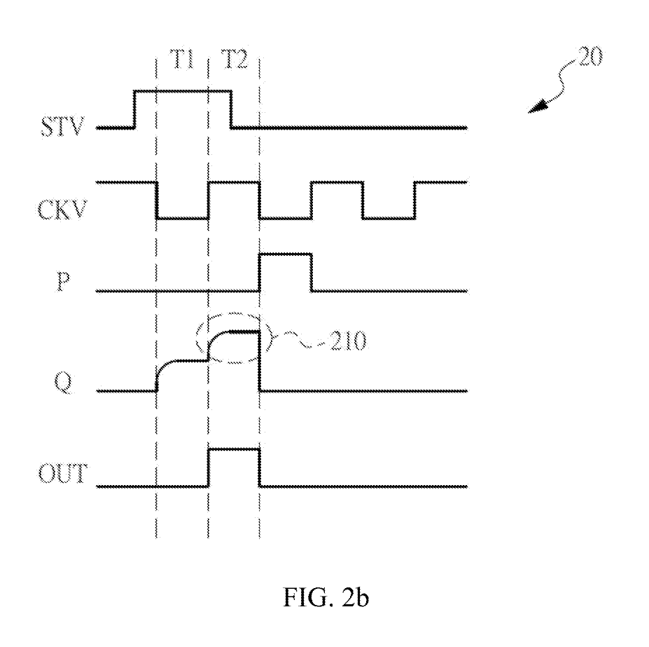

FIG. 2a is a schematic diagram of an exemplary ideal Thompson circuit and FIG. 2b is a schematic waveform diagram of an exemplary ideal Thompson circuit. Referring to FIG. 2a, a Thompson circuit 12 includes an input pulse signal circuit 120 and a frequency signal circuit 130. The input pulse signal circuit 120 is configured to provide a pre-charge power source to the Thompson circuit 12, so that when the frequency signal circuit 130 provides a frequency signal coupling, a high voltage level is achieved at a pull-up point. The Thompson circuit 12 includes: a first switch T10, where a control end 101a of the first switch T10 is electrically coupled to an input pulse signal STV, a first end 101b of the first switch T10 is electrically coupled to the input pulse signal STV, and a second end 101c of the first switch T10 is electrically coupled to a first node Q; a second switch T20, where a control end 201a of the second switch T20 is electrically coupled to a second node P, a first end 201b of the second switch T20 is electrically coupled to the first node Q, and a second end 201c of the second switch T20 is electrically coupled to a preset low potential Vss; a third switch T30, where a control end 301a of the third switch T30 is electrically coupled to the first node Q, a first end 301b of the third switch T30 is electrically coupled to a frequency signal CKV, and a second end 301c of the third switch T30 is electrically coupled to an output end OUT; and a fourth switch T40, where a control end 401a of the fourth switch T40 is electrically coupled to the second node P, a first end 401b of the fourth switch T40 is electrically coupled to the output end OUT, and a second end 401c of the fourth switch T40 is electrically coupled to the preset low potential Vss.

Referring to FIG. 2a and FIG. 2b, in an embodiment, when a waveform 20 of an ideal Thompson circuit is driven by a frequency signal T2, a waveform 210 output by the first node Q is maintained at a high potential.

Referring to FIG. 2a and FIG. 2b, in an embodiment, a capacitor C is added to a GOA circuit to help maintain a voltage, so that when the input pulse signal STV is switched off, it is expected that the potential of the first node Q is pulled up to continuously maintain a high potential until the frequency signal CKV changes from a low potential to a high potential, and then, the frequency signal CKV is transferred to the output end OUT for output. The potential of the first node Q needs to be high enough to completely transfer the frequency signal CKV to the output end OUT.

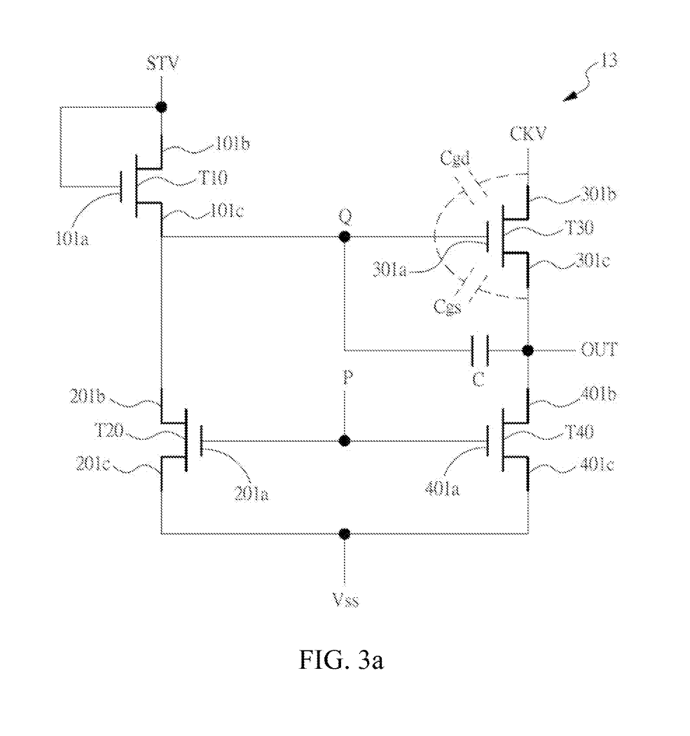

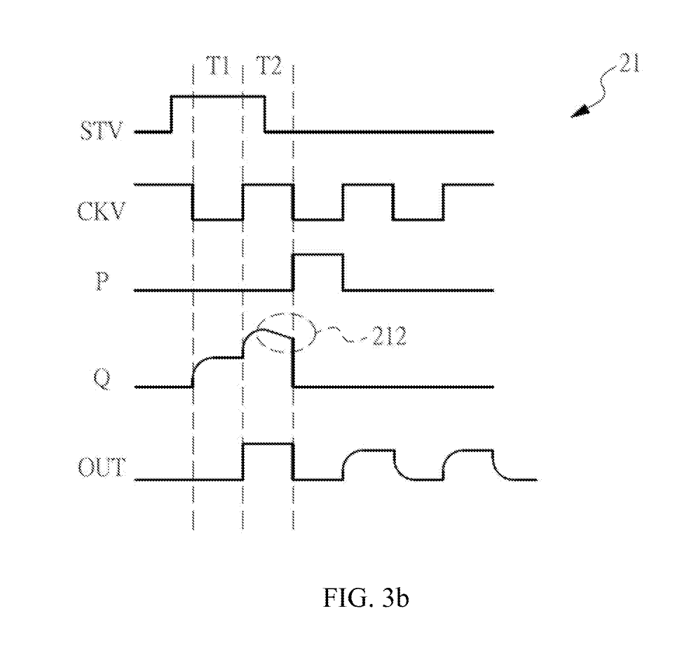

FIG. 3a is a schematic diagram of an exemplary actual Thompson circuit and FIG. 3b is a schematic waveform diagram of an exemplary actual Thompson circuit. Referring to FIG. 3a, a Thompson circuit 13 includes: a first switch T10, where a control end 101a of the first switch T10 is electrically coupled to an input pulse signal STV, a first end 101b of the first switch T10 is electrically coupled to the input pulse signal STV, and a second end 101c of the first switch T10 is electrically coupled to a first node Q; a second switch T20, where a control end 201a of the second switch T20 is electrically coupled to a second node P, a first end 201b of the second switch T20 is electrically coupled to the first node Q, and a second end 201c of the second switch T20 is electrically coupled to a preset low potential Vss; a third switch T30, where a control end 301a of the third switch T30 is electrically coupled to the first node Q, a first end 301b of the third switch T30 is electrically coupled to a frequency signal CKV, and a second end 301c of the third switch T30 is electrically coupled to an output end OUT; and a fourth switch T40, where a control end 401a of the fourth switch T40 is electrically coupled to the second node P, a first end 401b of the fourth switch T40 is electrically coupled to the output end OUT, and a second end 401c of the fourth switch T40 is electrically coupled to the preset low potential Vss. The third switch T30 is electrically coupled to parasitic capacitors Cgd and Cgs.

Referring to FIG. 3a and FIG. 3b, in an embodiment, when a waveform 21 of an actual Thompson circuit is driven by a frequency signal T2, a waveform 212 output by the first node Q is maintained at a potential lower than a potential of an ideal Thompson circuit.

Referring to FIG. 3a and FIG. 3b, in an embodiment, because the third switch T30 has a Cgd capacitance coupling, the potential of the first node Q is synchronously affected by the frequency signal CKV. When a voltage of the first node Q rises, the third switch T30 is slightly switched on. When the third switch T30 is switched on, a potential of the output end OUT oscillates with the frequency signal CKV, and a voltage of the first node Q may imperceptibly leak through the second switch T20.

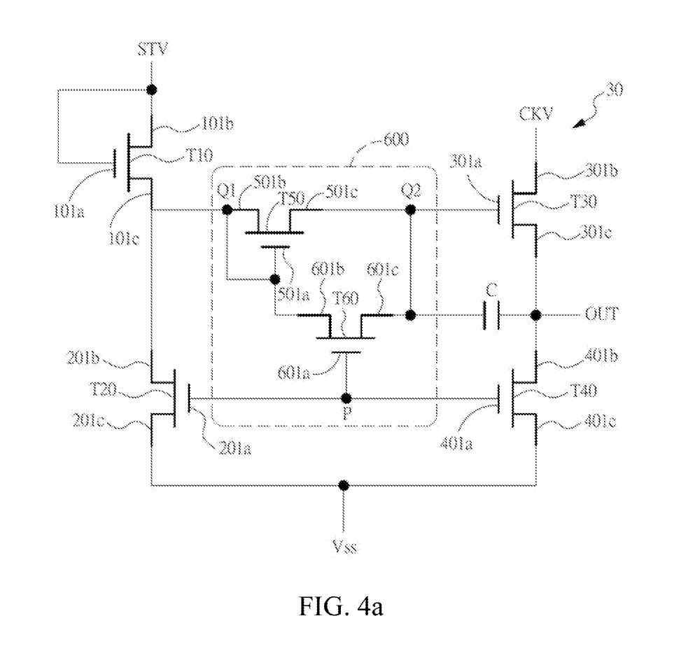

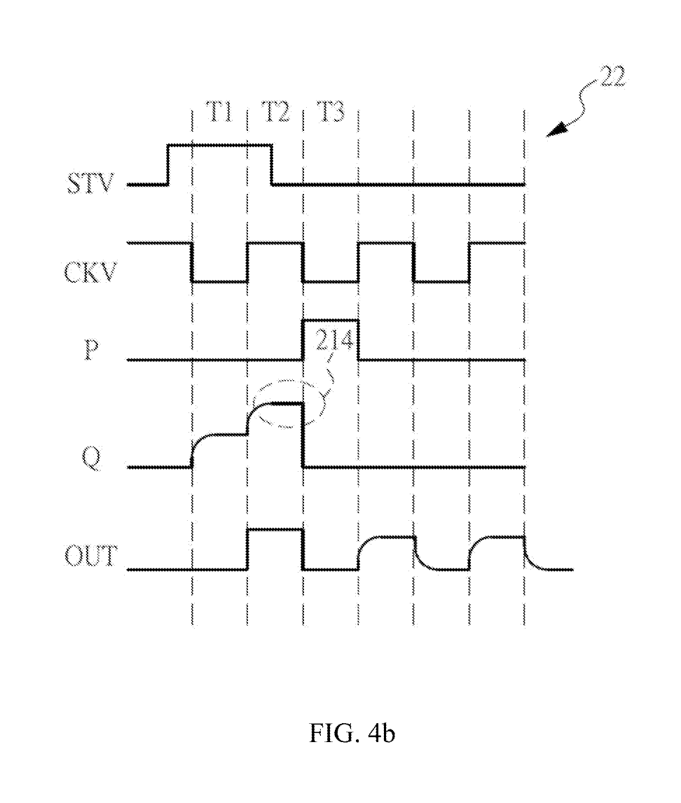

FIG. 4a is a schematic diagram of a shift register circuit according to an embodiment of this application and FIG. 4b is a schematic waveform diagram of a shift register circuit according to an embodiment of this application. Referring to FIG. 4a, in an embodiment of this application, a shift register circuit 30 includes a plurality of stages of shift registers, where each shift register includes: a first switch T10, where a control end 101a of the first switch T10 is electrically coupled to an input pulse signal STV, a first end 101b of the first switch T10 is electrically coupled to the input pulse signal STV, and a second end 101c of the first switch T10 is electrically coupled to a first node Q1; a second switch T20, where a control end 201a of the second switch T20 is electrically coupled to a second node P, a first end 201b of the second switch T20 is electrically coupled to the first node Q1, and a second end 201c of the second switch T20 is electrically coupled to a preset low potential Vss; a third switch T30, where a control end 301a of the third switch T30 is electrically coupled to the third node Q2, a first end 301b of the third switch T30 is electrically coupled to a frequency signal CKV, and a second end 301c of the third switch T30 is electrically coupled to an output end OUT; a fourth switch T40, where a control end 401a of the fourth switch T40 is electrically coupled to the second node P, a first end 401b of the fourth switch T40 is electrically coupled to the output end OUT, and a second end 401c of the fourth switch T40 is electrically coupled to the preset low potential Vss; and a voltage regulator circuit 600, configured to maintain a potential of the first node Q1 and a potential of the third node Q2 at a voltage level.

In an embodiment, the voltage regulator circuit 600 further includes a fifth switch T50, where a control end 501a of the fifth switch T50 is electrically coupled to the first node Q1, a first end 501b of the fifth switch T50 is electrically coupled to the first node Q1, and a second end 501c of the fifth switch T50 is electrically coupled to the third node Q2.

In an embodiment, the voltage regulator circuit 600 further includes a sixth switch T60, where a control end 601a of the sixth switch T60 is electrically coupled to the second node P, a first end 601b of the sixth switch T60 is electrically coupled to the first node Q1, and a second end 601c of the sixth switch T60 is electrically coupled to the third node Q2.

In an embodiment, a capacitor C configured to store an electric charge is further included, to maintain the potential of the third node Q2 at a voltage level.

In an embodiment, the first end 501b of the fifth switch T50 is electrically coupled to the first node Q1, to receive a high potential when the input pulse signal STV is switched on.

In an embodiment, the second end 501c of the fifth switch T50 is electrically coupled to the third node Q2, to transfer a high potential when the input pulse signal STV is switched on, so as to conduct the high potential from the first node Q1 to the third node Q2, thereby driving the third switch T30 to act.

In an embodiment, when acting, the third switch T30 may transfer a signal indicating that a frequency signal CKV changes from a low potential to a high potential to the output end OUT.

In an embodiment, a first end 601b of the sixth switch T60 is electrically coupled to the first node Q1, to receive a low potential when the input pulse signal STV is switched on.

In an embodiment, a second end 601c of the sixth switch T60 is electrically coupled to the third node Q2, to transfer a low potential when the input pulse signal STV is switched on, so as to conduct the low potential from the first node Q1 to the third node Q2, thereby preventing the third switch T30 from acting.

Referring to FIG. 4a and FIG. 4b, in an embodiment, when a waveform 22 of an ideal Thompson circuit is driven by a frequency signal T2, a waveform 214 output by the first node Q is maintained at a high potential.

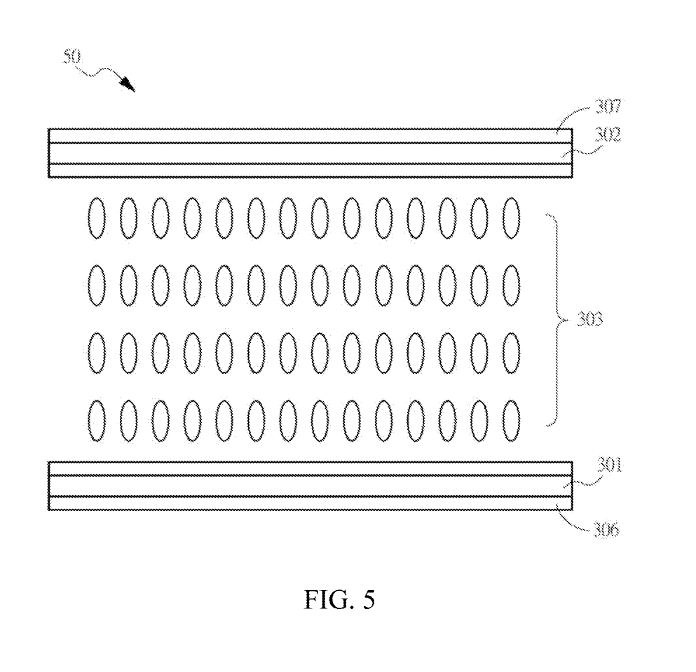

FIG. 5 is a schematic diagram of a liquid crystal display panel according to an embodiment of this application. Referring to FIG. 4a and FIG. 5, in an embodiment of this application, a display panel 50 includes: a first substrate 301 (for example, an active array substrate); a second substrate 302 (for example, a CF substrate), disposed opposite to the first substrate 301; a liquid crystal layer 303, disposed between the first substrate 301 and the second substrate 302; the shift register circuit 30, disposed between the first substrate 301 and the second substrate 302 (for example, located on a surface of the first substrate 301); a first polarizer 306 disposed on an outer surface of the first substrate 301; and a second polarizer 307 disposed on an outer surface of the second substrate 302, where a polarization direction of the first polarizer 306 is parallel to a polarization direction of the second polarizer 307.

In this application, two active switches are configured to control a node potential, so that a potential at a pull-up point can be prevented from an electrical leakage and maintained at a voltage level. In this way, a service life of a component is prolonged, and reliability of a product can be improved and a service life of the product can be prolonged.

The wordings such as “in some embodiments” and “in various embodiments” are repeatedly used. The wordings usually refer to different embodiments, but they may also refer to a same embodiment. The words, such as “comprise”, “have”, and “include”, are synonyms, unless other meanings are indicated in the context thereof.

The foregoing descriptions are merely preferred embodiments of this application, and are not intended to limit this application in any form. Although this application has been disclosed above through the preferred embodiments, the embodiments are not intended to limit this application. Any person skilled in the art can make some variations or modifications, namely, equivalent changes, according to the foregoing disclosed technical content to obtain equivalent embodiments without departing from the scope of the technical solutions of this application. Any simple amendment, equivalent change, or modification made to the foregoing embodiments according to the technical essence of this application without departing from the content of the technical solutions of this application shall fall within the scope of the technical solutions of this application.

What is claimed is:

1. A shift register circuit, comprising a plurality of stages of shift registers, wherein each shift register comprises:
a first switch, wherein a control end of the first switch is electrically coupled to an input pulse signal, a first end of the first switch is electrically coupled to the input pulse signal, and a second end of the first switch is electrically coupled to a first node;
a second switch, wherein a control end of the second switch is electrically coupled to a second node, a first end of the second switch is electrically coupled to the first node, and a second end of the second switch is electrically coupled to a preset low potential;
a third switch, wherein a control end of the third switch is electrically coupled to a third node, a first end of the third switch is electrically coupled to a frequency signal, and a second end of the third switch is electrically coupled to an output end;
a fourth switch, wherein a control end of the fourth switch is electrically coupled to the second node, a first end of the fourth switch is electrically coupled to the output end, and a second end of the fourth switch is electrically coupled to the preset low potential; and
a voltage regulator circuit, configured to maintain a potential of the first node and a potential of the third node at a voltage level.

2. The shift register circuit according to claim 1, wherein the voltage regulator circuit further comprises a fifth switch, wherein a control end of the fifth switch is electrically coupled to the first node, a first end of the fifth switch is electrically coupled to the first node, and a second end of the fifth switch is electrically coupled to the third node.

3. The shift register circuit according to claim 1, wherein the voltage regulator circuit further comprises a sixth switch, wherein a control end of the sixth switch is electrically coupled to the second node, a first end of the sixth switch is electrically coupled to the first node, and a second end of the sixth switch is electrically coupled to the third node.

4. The shift register circuit according to claim 1, further comprising a capacitor configured to store an electric charge, to maintain the potential of the third node at a voltage level.

5. The shift register circuit according to claim 2, wherein the first end of the fifth switch is electrically coupled to the first node, to receive a high potential when an input pulse signal is switched on.

6. The shift register circuit according to claim 2, wherein the second end of the fifth switch is electrically coupled to the third node, to transfer a high potential when an input pulse signal is switched on.

7. The shift register circuit according to claim 6, wherein the high potential is conducted from the first node to the third node, to drive the third switch to act.

8. The shift register circuit according to claim 7, wherein when acting, the third switch may transfer a signal indicating that a frequency signal changes from a low potential to a high potential to the output end.

9. The shift register circuit according to claim 3, wherein a first end of the sixth switch is electrically coupled to the first node, to receive a low potential when an input pulse signal is switched on.

10. The shift register circuit according to claim 3, wherein a second end of the sixth switch is electrically coupled to the third node, to transfer a low potential when an input pulse signal is switched on, so as to conduct the low potential from the first node to the third node, thereby preventing the third switch from acting.

11. A display panel, comprising:
a first substrate;
a second substrate, disposed opposite to the first substrate; and
a shift register circuit, disposed on the first substrate or the second substrate and comprising a plurality of stages of shift registers, wherein each shift register comprises:
a first switch, wherein a control end of the first switch is electrically coupled to an input pulse signal, a first end of the first switch is electrically coupled to the input pulse signal, and a second end of the first switch is electrically coupled to a first node;
a second switch, wherein a control end of the second switch is electrically coupled to a second node, a first end of the second switch is electrically coupled to the first node, and a second end of the second switch is electrically coupled to a preset low potential;
a third switch, wherein a control end of the third switch is electrically coupled to a third node, a first end of the third switch is electrically coupled to a frequency signal, and a second end of the third switch is electrically coupled to an output end;
a fourth switch, wherein a control end of the fourth switch is electrically coupled to the second node, a first end of the fourth switch is electrically coupled to the output end, and a second end of the fourth switch is electrically coupled to the preset low potential; and
a voltage regulator circuit, configured to maintain a potential of the first node and a potential of the third node at a voltage level.

12. The display panel according to claim 11, wherein the voltage regulator circuit further comprises a fifth switch, wherein a control end of the fifth switch is electrically coupled to the first node, a first end of the fifth switch is electrically coupled to the first node, and a second end of the fifth switch is electrically coupled to the third node.

13. The display panel according to claim 11, wherein the voltage regulator circuit further comprises a sixth switch, wherein a control end of the sixth switch is electrically coupled to the second node, a first end of the sixth switch is electrically coupled to the first node, and a second end of the sixth switch is electrically coupled to the third node.

14. The display panel according to claim 11, further comprising a capacitor configured to store an electric charge, to maintain the potential of the third node at a voltage level.

15. The display panel according to claim 12, wherein a first end of the fifth switch is electrically coupled to the first node, to receive a high potential when an input pulse signal is switched on.

16. The display panel according to claim 12, wherein a second end of the fifth switch is electrically coupled to the third node, to transfer a high potential when an input pulse signal is switched on, so as to conduct the high potential from the first node to the third node, thereby driving a third switch to act.

17. The display panel according to claim 16, wherein when acting, the third switch may transfer a signal indicating that a frequency signal changes from a low potential to a high potential to the output end.

18. The display panel according to claim 13, wherein a first end of the sixth switch is electrically coupled to the first node, to receive a low potential when an input pulse signal is switched on.

19. The display panel according to claim 13, wherein a second end of the sixth switch is electrically coupled to the third node, to transfer a low potential when an input pulse signal is switched on, so as to conduct the low potential from the first node to the third node, thereby preventing a third switch from acting.

20. A shift register circuit, comprising a plurality of stages of shift registers, wherein each shift register comprises:
a first switch, wherein a control end of the first switch is electrically coupled to an input pulse signal, a first end of the first switch is electrically coupled to the input pulse signal, and a second end of the first switch is electrically coupled to a first node;
a second switch, wherein a control end of the second switch is electrically coupled to a second node, a first end of the second switch is electrically coupled to the first node, and a second end of the second switch is electrically coupled to a preset low potential;
a third switch, wherein a control end of the third switch is electrically coupled to a third node, a first end of the third switch is electrically coupled to a frequency signal, and a second end of the third switch is electrically coupled to an output end;
a fourth switch, wherein a control end of the fourth switch is electrically coupled to the second node, a first end of the fourth switch is electrically coupled to the output end, and a second end of the fourth switch is electrically coupled to the preset low potential;
a voltage regulator circuit, comprising a fifth switch and a sixth switch, to maintain a potential of the first node and a potential of the third node at a voltage level; and
a capacitor, configured to store an electric charge, to maintain the potential of the third node at a voltage level, wherein
a control end of the fifth switch is electrically coupled to the first node, a first end of the fifth switch is electrically coupled to the first node, to receive a high potential when an input pulse signal is switched on, and a second end of the fifth switch is electrically coupled to the third node, to transfer a high potential when an input pulse signal is switched on; and
a control end of the sixth switch is electrically coupled to the second node, a first end of the sixth switch is electrically coupled to the first node, to receive a low potential when an input pulse signal is switched on, and a second end of the sixth switch is electrically coupled to the third node, to transfer a low potential when an input pulse signal is switched on.
